(19) United States
(12) Patent Application Publication
(10) Pub. No.: US 2024/0389285 A1
(43) Pub. Date: Nov. 21, 2024

(54) SELECTIVE INSULATION OF MOUNT POINTS

(71) Applicant: Apple Inc., Cupertino, CA (US)

(72) Inventors: Laura M. CAMPO, Santa Clara, CA (US); Samuel A. RESNICK, San Francisco, CA (US); Dragos MOROIANU, Cupertino, CA (US); Sivesh SELVAKUMAR, San Francisco, CA (US); Jason C. SAUERS, Sunnyvale, CA (US); Phil M. HOBSON, Menlo Park, CA (US)

(21) Appl. No.: 18/689,837

(22) PCT Filed: Sep. 16, 2022
(86) PCT No.: PCT/US2022/043883

§ 371 Date: Mar. 6, 2024

Related U.S. Application Data
(60) Provisional application No. 63/246,753, filed on Sep. 21, 2021.

(51) Int. Cl. H05K 7/20; H05K 5/02

(52) U.S. Cl. CPC H05K 7/20963; H05K 5/0217

(57) ABSTRACT

An electronic device is provided that includes a heatsink, an electrical circuit mounted on the heatsink, and a chassis. A plurality of heat-insulating connectors mounting the heatsink to the chassis at a first plurality of mount points, and a plurality of heat-conducting connectors mounting the heatsink to the chassis at a second plurality of mount points. The first plurality of mount points are located closer to the electrical circuit mounted on the heatsink than the second plurality of mount points.

### CROSS-REFERENCE TO RELATED APPLICATION

This application claims the benefit of U.S. Provisional Application No. 63/246,753, entitled “SELECTIVE INSULATION OF MOUNT POINTS OF ELECTRONIC DEVICE,” filed Sep. 21, 2021, the entirety of which is incorporated herein by reference.

### TECHNICAL FIELD

The present description relates generally to electronic devices including, for example, the management of heat generated in electronic devices.

### BACKGROUND

Electronic devices may include electrical components that generate heat during operation of the devices. Cooling devices such as fans and heatsinks may be used to help dissipate the heat generated by the electrical components. The design and arrangement of electronic devices are important for devices such as head-mountable devices that are typically used in close proximity to a user's body.

### BRIEF DESCRIPTION OF THE DRAWINGS

Certain features of the subject technology are set forth in the appended claims. However, for purpose of explanation, several embodiments of the subject technology are set forth in the following figures.

FIG. 1 is a diagram illustrating components of a head-mountable device as an example of an electronic device according to aspects of the subject technology.

FIG. 2A is a cross-sectional view of a heat-conducting connector and FIG. 2B is a cross-sectional view of a heat-insulating connector according to aspects of the subject technology.

FIG. 3A is a cross-sectional view of a heat-conducting connector and FIG. 3B is a cross-sectional view of a heat-insulating connector according to aspects of the subject technology.

FIGS. 4A to 4C depict cross-sectional views of mount points using screws as the mechanical connector according to aspects of the subject technology.

FIGS. 5A to 5C depicts cross-sectional views of mount points using rivets as the mechanical connector according to aspects of the subject technology.

FIG. 6 illustrates a block diagram of a head-mountable device, in accordance with some embodiments of the present disclosure.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

The performance of electronic devices may be limited by a touch-temperature constraint which limits the maximum temperature on the surfaces of enclosures of the electronic devices. Touch-temperature constraints are particularly significant for electronic devices that come into contact with sensitive areas of a user's body, such as head-mounted devices. In order to maximize thermal performance it is desirable to spread heat uniformly over enclosures or other components of the electronic devices and to mitigate the temperature of localized hotspots. Thermal components like heat spreaders or active cooling components like fans or blowers may be used to spread the generated heat. However, these components add size, weight, cost, and complexity to the electronic devices.

The subject technology proposes to selectively tune thermal conduction paths within an electronic device using existing structural elements to optimize temperature distribution within the electronic device. Electrical circuits or circuits such as a chip mounted on a printed circuit board generate heat which is then conducted through structural elements to an enclosure of the electronic device. According to aspects of the subject technology, heat-insulating connectors and heat-conducting connectors are used at different mount points to mount the structural elements. For example, mount points that are closest to the electrical circuit may use heat-insulating connectors to mount the structural elements while mount points farthest from the electrical circuit may use heat-conducting connectors to mount the structural elements. In this manner, localized hotspots near the electrical circuit may be mitigated by tuning thermal conduction paths through the farthest mount points from the electrical circuit.

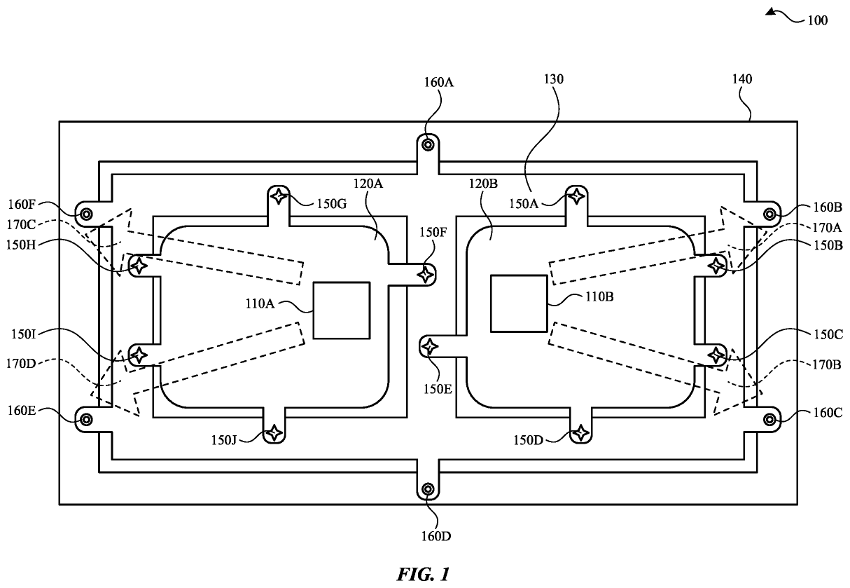

FIG. 1 is a diagram illustrating components of a head-mountable device as an example of an electronic device according to aspects of the subject technology. Not all of the depicted components may be used in all implementations, however, and one or more implementations may include additional or different components than those shown in the figure. Variations in the arrangement and type of the components may be made without departing from the spirit or scope of the claims as set forth herein. Additional components, different components, or fewer components may be provided.

As depicted in FIG. 1, head-mountable device 100 includes electrical circuits 110A and 110B, heatsinks 120A and 120B, chassis 130, enclosure 140, mechanical connectors 150A-150J, and mechanical connectors 160A-160F. Electrical circuits 110A and 110B represent one or more chips mounted on a printed circuit board, which may be single layer or multi-layer. The chips may be controllers, drivers, memory, etc. Electrical circuits 110A and 110B generate heat during their operation. To help in dissipating the heat, electrical circuits 110A and 110B may be mounted on heatsinks 120A and 120B, respectively. Heatsinks 120A and 120B represent mechanical heat spreaders that may be passive (e.g., copper plate) or active (e.g., fan).

Heatsinks 120A and 120B may be mounted to chassis 130 using connectors 150A-150J at corresponding mount points on chassis 130. According to aspects of the subject technology, connectors 150A-150J may include mechanical connectors such as screws or rivets. However, other types of connectors and connection mechanisms including, but not limited to, sonic welding, melding, adhesives, etc. may be used without departing from the scope of the subject technology.

Chassis 130 may be mounted to enclosure 140 using connectors 160A-160F at corresponding mount points on enclosure 140. According to aspects of the subject technology, connectors 160A-160F may include mechanical connectors such as rivets or screws. However, other types of connectors and connection mechanisms including, but not limited to, sonic welding, melding, adhesives, etc. may be used without departing from the scope of the subject technology.

As noted above, the subject technology proposes to selectively tune thermal conduction paths between components of head-mountable device 100. In this regard, a first group of connectors selected from connectors 150A-150F are configured as heat-conducting connectors and a second group of connectors selected from connectors 150A-150F are configured as heat-insulating connectors. Similarly, a first group of connectors selected from connectors 160A-160F are configured as heat-conducting connectors and a second group of connectors selected from connectors 160A-160F are configured as heat-insulating connectors.

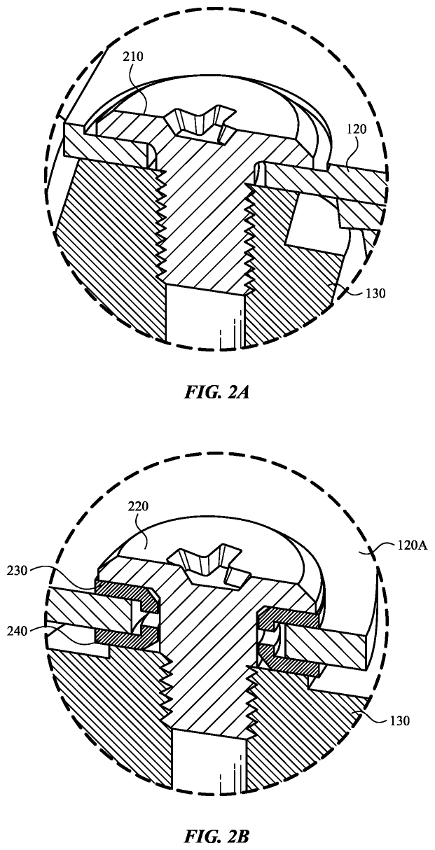

FIG. 2A is a cross-sectional view of a heat-conducting connector and FIG. 2B is a cross-sectional view of a heat-insulating connector according to aspects of the subject technology. Not all of the depicted components may be used in all implementations, however, and one or more implementations may include additional or different components than those shown in the figure. Variations in the arrangement and type of the components may be made without departing from the spirit or scope of the claims as set forth herein. Additional components, different components, or fewer components may be provided.

As depicted in FIG. 2A, heatsink 120A is mounted to chassis 130 at a mount point using screw 210. Screw 210 may be made of a metal to conduct both heat and electricity between heatsink 120A and chassis 130. Turning to FIG. 2B, heatsink 120A is mounted to chassis 130 at a mount point using screw 220. Unlike screw 210 in FIG. 2B, screw 220 is separated from heatsink 120A by a first insulating layer 230. In addition heatsink 120A is separated from chassis 130 by a second insulating layer 240. Insulating layers 230 and 240 may be washers made of plastic or another material that reduces the conductivity of heat and electricity between heatsink 120A and chassis 130. Different thicknesses of insulating layers 230 and 240 may be used for different heat-insulating connectors to vary the thermal conductivity of the thermal path going through that connector. In addition, screw 220 may be made of plastic or another heat-insulating material.

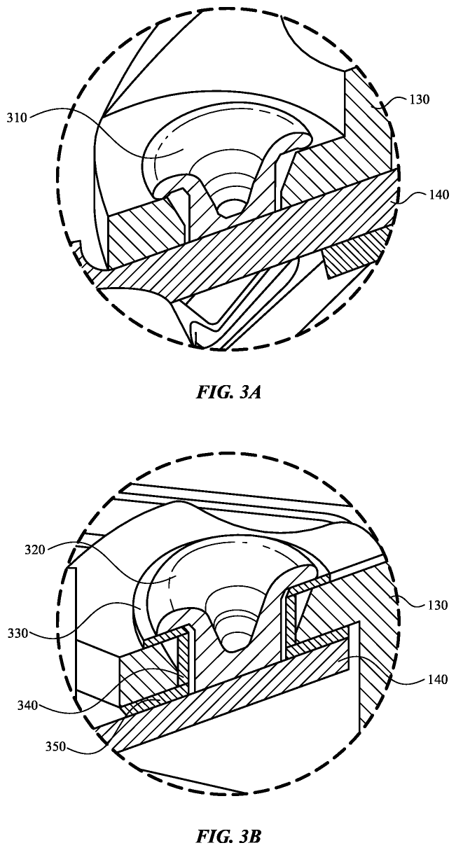

FIG. 3A is a cross-sectional view of a heat-conducting connector and FIG. 3B is a cross-sectional view of a heat-insulating connector according to aspects of the subject technology. Not all of the depicted components may be used in all implementations, however, and one or more implementations may include additional or different components than those shown in the figure. Variations in the arrangement and type of the components may be made without departing from the spirit or scope of the claims as set forth herein. Additional components, different components, or fewer components may be provided.

As depicted in FIG. 3A, chassis 130 is mounted to enclosure 140 at a mount point using rivet 310. Rivet 310 may be made of a metal to conduct both heat and electricity between chassis 130 and enclosure 140. Turning to FIG. 3B, chassis 130 is mounted to enclosure 140 at a mount point using rivet 320. Unlike rivet 310, rivet 320 is separated from chassis 130 by a first insulating layer 330 and an insulating sleeve 340. In addition, chassis 130 is separated from enclosure 140 by insulating layer 350. Insulating layers 330 and 350 may be washers made of plastic or another material that reduces conductivity of heat and electricity between chassis 130 and enclosure 140. Insulating sleeve 340 may be made of the same material as insulating layers 330 and 350. Alternatively, insulating sleeve 340 may be made of a less rigid material than that used for insulating layers 330 and 350 to allow for deformation of insulating sleeve 340 as rivet 320 is secured to mount chassis 130 to enclosure 140 while minimizing the compression of insulating layers 330 and 350 during the mounting process. Different thicknesses of insulating layers 330 and 350 may be used for different heat-insulating connectors to vary the thermal conductivity of the thermal path going through that connector.

Referring back to FIG. 1, each of connectors 150A-150J and connectors 160A-160F attaches two structural elements of head-mountable device 100 at a respective mount point. To tune the thermal conduction paths for the dissipation of heat generated by electrical circuits 110A and 110B, some of the mount points are selected to use a heat-insulating connector while other mount points are selected to use a heat-conducting insulator. The thermal conduction paths may be tuned to dissipate heat as uniformly as possible throughout the structural elements of head-mountable device 100. Alternatively, the thermal conduction paths may be tuned to focus heat dissipation on certain areas within head-mountable device 100. The selection of mount points for each type of connector may be made using simulations of heat dissipation through head-mountable device 100 or through trial-and-error processes on working models of head-mountable device 100.

According to aspects of the subject technology, mount points for each type of connector may be selected to dissipate heat as uniformly as possible by selecting mount points closest to the heat sources (e.g., electrical circuits 110A and 110B) for heat-insulating connectors and mount points farthest from the heat sources for heat-conducting connectors. With reference to FIG. 1, mount points for connectors 150B, 150C, 150H, and 150I for connecting heatsinks 120A and 120B to chassis 130 may be selected for heat-conducting connectors, while mount points for connectors 150A, 150D, 150E, 150F, 150G, and 150J may be selected for heat-insulating connectors. Similarly, mount points for connectors 160B, 1600, 160E, and 160F for connecting chassis 130 to enclosure 140 may be selected for heat-conducting connectors, while mount points for connectors 160A and 160D may be selected for heat-insulating connectors. Selecting the connectors in the foregoing manner tunes thermal conduction paths to flow in the directions illustrated by arrows 170A, 170B, 170C, and 170D away from the center of head-mountable device 100 which may contact the user's nose and areas around the user's eyes. The subject technology is not limited to this configuration of heat-conducting connectors and heat-insulating connectors, which may vary depending on design requirements and method used to select the different mount points for the different types of connectors.

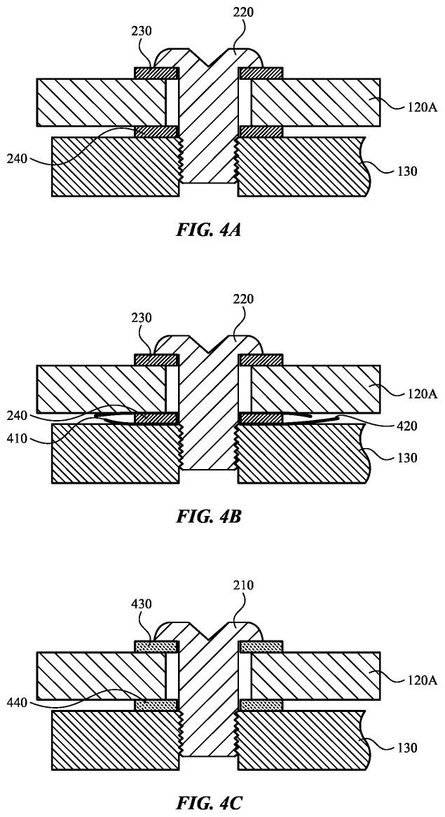

The design of head-mountable device 100 may require electrically coupling the structural components while maintaining the selection and position of the heat-insulating connectors and heat-conducting connectors. For example, grounding paths may need to be maintained between structural elements. Various techniques may be used to facilitate electrically coupling two structural components at a mount point using a heat-insulating connector. FIGS. 4A to 4C depict cross-sectional views of mount points using screws as the mechanical connector according to aspects of the subject technology.

FIG. 4A depicts a fully insulated connection using a heat-insulating connector comprising screw 220 and heat-insulating layers 230 and 240 insulating screw 220 from heatsink 120A and insulating heatsink 120A from chassis 130. The heat-insulating layers 230 and 240 may be in the form of washers and made up of a material like plastic that insulates both heat and electricity. In addition, the screw may be made of a plastic or another insulating material. FIG. 4C depicts a fully coupled connection using a heat-conducting connector comprising screw 210 and, in this example, conducting layers 430 and 440 in the form of washers made of conductive material. In this example, there is both heat and electricity conducted between heatsink 120A and chassis 130. FIG. 4B provides a hybrid approach to the connection. The arrangement of FIG. 4B uses the heat-insulating layers 230 and 240, similar to what is shown in FIG. 4A, but places a conductive wire between heatsink 120A and chassis 130 to facility electrical conduction between these two elements. The conductive wire may be of a diameter between .1 and.5 mm and made of any conductive material such as copper, but the subject technology is not limited to this range of diameters or material. The relatively small conductive wire has a minimal impact on the heat insulating properties of the connection due to its small size but allows electrical coupling for grounding or other purposes between the structural components.

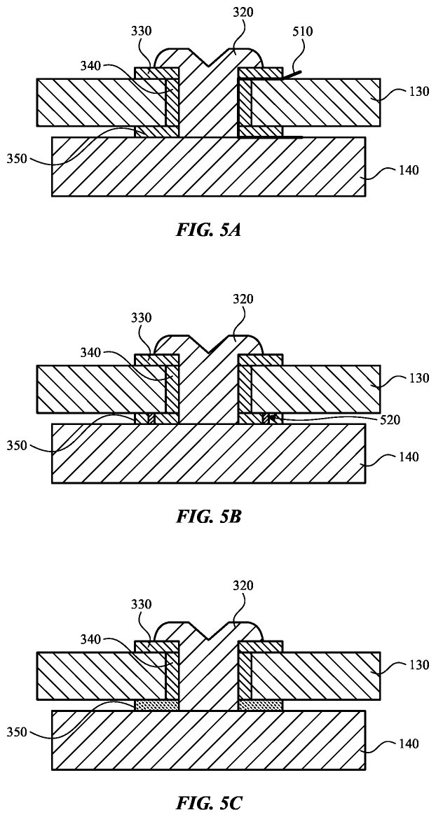

FIGS. 5A to 5C depicts cross-sectional views of mount points using rivets as the mechanical connector according to aspects of the subject technology. FIG. 5A depicts rivet 320 used to couple chassis 130 to enclosure 140. Heat insulating layers 330 and 350 together with heat-insulating sleeve 340 make this a heat-insulating connector. Similar to FIG. 4B discussed above, conductive wire 510 is placed between chassis 130 and enclosure 140 to electrically couple the two components for grounding or other electrical purposes while still maintaining most of the heat-insulating properties of the connection.

FIG. 5B depicts an alternative arrangement in which conductive pins 520 are manufactured within insulating layer 350 and are oriented to electrically couple chassis 130 to enclosure 140. Conductive pins 520 may be made of any conductive material, such as copper for example. The number of pins may vary depending on the electrical needs of the connection while minimizing heat conductivity between the two structural components. For example, the number of pins may range from one to ten with each pin having a diameter of approximately 0.2 mm to 1 mm where larger diameters may require fewer pins. FIG. 5C depicts another alternative arrangement in which insulating layer 350 is manufactured to contain conductive particles. The conductive particles may be made of any conductive material, such as copper for example. The density of the conductive particles within the insulating material of insulating layer 350 may vary depending on the electrical needs of the connection while minimizing heat conductivity between the two structural components. Particle diameter may range from approximately 10 nm to 10 microns. While the solutions represented by FIGS. 5B and 5C have been described as being used with rivets as the mechanical connector, these solutions also may be used with other types of mechanical connectors, such as screws.

Using the arrangements described above, thermal conduction paths may be tuned to dissipate heat more uniformly through structural elements of electronic device such as head-mountable devices. The use of thermally-conductive connectors increases heat conductivity along the thermal conduction paths containing those connectors, while the use of thermally-insulating connectors decreases the heat conductivity along the thermal paths containing those connectors. With more uniform heat dissipation, more power can be used by the electrical circuits without violating temperature constraints on the structural elements of the device.

The head-mountable device can be worn by a user to display visual information within the user's field of view. The head-mountable device can be used as a virtual reality system, an augmented reality system, and/or a mixed reality system. A user may observe outputs provided by the head-mountable device, such as visual information provided on a display. The display can optionally allow a user to observe a physical environment outside of the head-mountable device. A physical environment refers to a physical world that people can interact with and/or sense without necessarily requiring the aid of an electronic device. A computer-generated reality environment relates to a partially or wholly simulated environment that people sense and/or interact with the assistance of an electronic device. Examples of computer-generated reality include, but are not limited to, mixed reality and virtual reality. Examples of mixed realities can include augmented reality and augmented virtuality. Examples of electronic devices that enable a person to sense and/or interact with various computer-generated reality environments include head-mountable devices, projection-based devices, heads-up displays (HUDs), vehicle windshields having integrated display capability, windows having integrated display capability, displays formed as lenses designed to be placed on a person's eyes (e.g., similar to contact lenses), headphones/earphones, speaker arrays, input devices (e.g., wearable or handheld controllers with or without haptic feedback), smartphones, tablets, and desktop/laptop computers. A head-mountable device can have an integrated opaque display, have a transparent or translucent display, or be configured to accept an external opaque display from another device (e.g., smartphone).

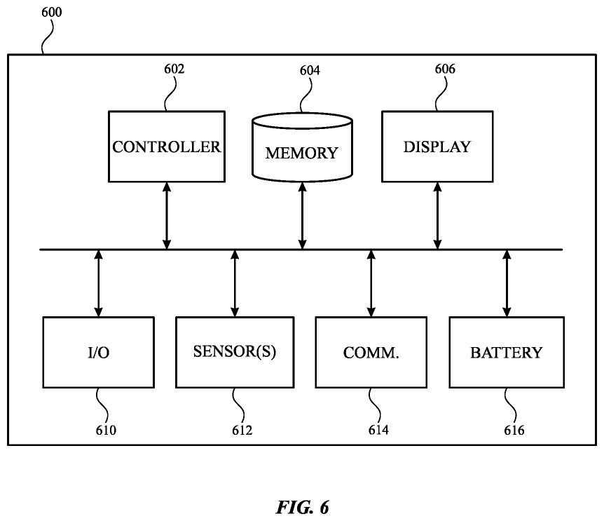

FIG. 6 is a block diagram of head-mountable device 100 according to aspects of the subject technology. It will be appreciated that components described herein can be provided on either or both of a frame and/or a securement element of the head-mountable device 100. It will be understood that additional components, different components, or fewer components than those illustrated may be utilized within the scope of the subject disclosure.

As shown in FIG. 6, the head-mountable device 100 can include a controller 602 (e.g., control circuity) with one or more processing units that include or are configured to access a memory 604 having instructions stored thereon. The instructions or computer programs may be configured to perform one or more of the operations or functions described with respect to the head-mountable device 100. The controller 602 can be implemented as any electronic device capable of processing, receiving, or transmitting data or instructions. For example, the controller 602 may include one or more of: a microprocessor, a central processing unit (CPU), an application-specific integrated circuit (ASIC), a digital signal processor (DSP), or combinations of such devices. As described herein, the term “processor” is meant to encompass a single processor or processing unit, multiple processors, multiple processing units, or other suitably configured computing element or elements.

The memory 604 can store electronic data that can be used by the head-mountable device 100. For example, the memory 604 can store electrical data or content such as, for example, audio and video files, documents and applications, device settings and user preferences, timing and control signals or data for the various modules, data structures or databases, and so on. The memory 604 can be configured as any type of memory. By way of example only, the memory 604 can be implemented as random access memory, read-only memory, Flash memory, removable memory, or other types of storage elements, or combinations of such devices.

The head-mountable device 100 can further include a display unit 606 for displaying visual information for a user. The display unit 606 can provide visual (e.g., image or video) output. The display unit 606 can be or include an opaque, transparent, and/or translucent display. The display unit 606 may have a transparent or translucent medium through which light representative of images is directed to a user's eyes. The display unit 606 may utilize digital light projection, OLEDs, LEDs, uLEDs, liquid crystal on silicon, laser scanning light source, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface. The head-mountable device 100 can include an optical subassembly configured to help optically adjust and correctly project the image based content being displayed by the display unit 606 for close up viewing. The optical subassembly can include one or more lenses, mirrors, or other optical devices.

The head-mountable device 100 can include an input/output component 610, which can include any suitable component for connecting head-mountable device 100 to other devices. Suitable components can include, for example, audio/video jacks, data connectors, or any additional or alternative input/output components. The input/output component 610 can include buttons, keys, or another feature that can act as a keyboard for operation by the user. Input/output component 610 may include a microphone. The microphone may be operably connected to the controller 602 for detection of sound levels and communication of detections for further processing, as described further herein. Input/output component 610 also may include speakers. The speakers can be operably connected to the controller 602 for control of speaker output, including sound levels, as described further herein.

The head-mountable device 100 can include one or more other sensors 612. Such sensors can be configured to sense substantially any type of characteristic such as, but not limited to, images, pressure, light, touch, force, temperature, position, motion, and so on. For example, the sensor can be a photodetector, a temperature sensor, a light or optical sensor, an atmospheric pressure sensor, a humidity sensor, a magnet, a gyroscope, an accelerometer, a chemical sensor, an ozone sensor, a particulate count sensor, and so on. By further example, the sensor can be a bio-sensor for tracking biometric characteristics, such as health and activity metrics. Other user sensors can perform facial feature detection, facial movement detection, facial recognition, eye tracking, user mood detection, user emotion detection, voice detection, etc. Sensors can include a camera which can capture image based content of the outside world.

The head-mountable device 100 can include communications circuitry 614 for communicating with one or more servers or other devices using any suitable communications protocol. For example, communications circuitry 614 can support Wi-Fi (e.g., a 802.11 protocol), Ethernet, Bluetooth, high frequency systems (e.g., 900 MHz, 2.4 GHz, and 5.6 GHz communication systems), infrared, TCP/IP (e.g., any of the protocols used in each of the TCP/IP layers), HTTP, BitTorrent, FTP, RTP, RTSP, SSH, any other communications protocol, or any combination thereof. Communications circuitry 614 can also include an antenna for transmitting and receiving electromagnetic signals.

The head-mountable device 100 can include a battery 616, which can charge and/or power components of the head-mountable device 100. The battery can also charge and/or power components connected to the head-mountable device 100.

While various embodiments and aspects of the present disclosure are illustrated with respect to a head-mountable device, it will be appreciated that the subject technology can encompass and be applied to other electronic devices. Such an electronic device can be or include a desktop computing device, a laptop-computing device, a display, a television, a portable device, a phone, a tablet computing device, a mobile computing device, a wearable device, a watch, and/or a digital media player.

According to aspects of the subject technology, an electronic device is provided that includes a heatsink, an electrical circuit mounted on the heatsink, and a chassis. A plurality of heat-insulating connectors mounting the heatsink to the chassis at a first plurality of mount points, and a plurality of heat-conducting connectors mounting the heatsink to the chassis at a second plurality of mount points. The first plurality of mount points are located closer to the electrical circuit mounted on the heatsink than the second plurality of mount points.

Each heat-insulating connector of the plurality of heat-insulating connectors may include a mechanical connector and an insulating layer separating the mechanical connector from the heatsink or the chassis and separating the heatsink from the chassis. A first insulating layer of a first heat-insulating connector may have a first thickness greater than a second thickness of a second insulating layer of a second heat-insulating connector.

One or more heat-insulating connectors of the plurality of heat-insulating connectors may include an electrically conductive wire electrically coupling the heatsink to the chassis. The insulating layer of one or more heat-insulating connectors of the plurality of heat-insulating connectors may include electrically conductive particles to electrically couple the heatsink to the chassis. The insulating layer of one or more heat-insulating connectors of the plurality of heat-insulating connectors may include electrically conductive pins to electrically couple the heatsink to the chassis.

The mechanical connector may be a screw or a rivet. The heatsink may include a fan pillow heatsink.

According to aspects of the subject technology, a head-mountable device is provided that includes a heatsink, an electrical circuit mounted on the heatsink, a display unit coupled to the electrical circuit, and a chassis. A first plurality of heat-insulating connectors mount the heatsink to the chassis at a first plurality of mount points and a first plurality of heat-conducting connectors mount the heatsink to the chassis at a second plurality of mount points. The head-mountable device further includes an enclosure, where a second plurality of heat-insulating connectors mount the chassis to the enclosure at a third plurality of mount points, and a second plurality of heat-conducting connectors mount the chassis to the enclosure at a fourth plurality of mount points. The first plurality of mount points are located closer to the electrical circuit mounted on the heatsink than the second plurality of mount points, and the third plurality of mount points are closer to the electrical circuit mounted on the heatsink than the fourth plurality of mount points.

Each heat-insulating connector of the first and second pluralities of heat-insulating connectors may include a mechanical connector and an insulating layer separating the mechanical connector from the heatsink and the chassis. One or more heat-insulating connectors of the first and second pluralities of heat-insulating connectors may include an electrically conductive wire electrically coupling the heatsink to the chassis or the chassis to the enclosure. The insulating layer of one or more heat-insulating connectors of the first and second pluralities of heat-insulating connectors may include electrically conductive particles to electrically couple the heatsink to the chassis or the chassis to the enclosure. The insulating layer of one or more heat-insulating connectors of the first and second pluralities of heat-insulating connectors may include electrically conductive pins to electrically couple the heatsink to the chassis or the chassis to the enclosure.

The mechanical connector may be a screw or a rivet. The heatsink may include a fan pillow heatsink.

According to aspects of the subject technology, an electronic device is provided that includes a heatsink, an electrical circuit mounted on the heatsink, and a chassis. A plurality of heat-insulating connectors mount the heatsink to the chassis at a first plurality of mount points and a plurality of heat-conducting connectors mount the heatsink to the chassis at a second plurality of mount points.

The second plurality of mount points may be arranged within respective tuned thermal conduction paths between the electrical circuit and the chassis via the heatsink and the plurality of heat-conducting connectors. The first plurality of mount points may be located closer to the electrical circuit mounted on the heatsink than the second plurality of mount points. Each heat-insulating connector of the plurality of heat-insulating connectors may include a mechanical connector and an insulating layer separating the mechanical connector from the heatsink or the chassis and separating the heatsink from the chassis. The insulating layer may include an electrically conductive element to electrically couple the heatsink to the chassis.

As described herein, aspects of the present technology can include the gathering and use of data. The present disclosure contemplates that in some instances, gathered data can include personal information or other data that uniquely identifies or can be used to locate or contact a specific person. The present disclosure contemplates that the entities responsible for the collection, analysis, disclosure, transfer, storage, or other use of such personal information or other data will comply with well-established privacy practices and/or privacy policies. The present disclosure also contemplates embodiments in which users can selectively block the use of or access to personal information or other data (e.g., managed to minimize risks of unintentional or unauthorized access or use).

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the invention. The word exemplary is used to mean serving as an example or illustration. To the extent that the term include, have, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, and systems can generally be integrated together in a single software/hardware product or packaged into multiple software/hardware products.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language of the claims and to encompass all legal equivalents. Notwithstanding, none of the claims are intended to embrace subject matter that fails to satisfy the requirements of the applicable patent law, nor should they be interpreted in such a way.

What is claimed is:

1. An electronic device, comprising:
a heatsink;
an electrical circuit mounted on the heatsink;
a chassis;
a plurality of heat-insulating connectors mounting the heatsink to the chassis at a first plurality of mount points; and
a plurality of heat-conducting connectors mounting the heatsink to the chassis at a second plurality of mount points,
wherein the first plurality of mount points are located closer to the electrical circuit mounted on the heatsink than the second plurality of mount points.

2. The electronic device of claim 1, wherein each heat-insulating connector of the plurality of heat-insulating connectors comprises:
a mechanical connector; and
an insulating layer separating the mechanical connector from the heatsink or the chassis and separating the heatsink from the chassis.

3. The electronic device of claim 2, wherein a first insulating layer of a first heat-insulating connector has a first thickness greater than a second thickness of a second insulating layer of a second heat-insulating connector.

4. The electronic device of claim 2, wherein one or more heat-insulating connectors of the plurality of heat-insulating connectors comprises an electrically conductive wire electrically coupling the heatsink to the chassis.

5. The electronic device of claim 2, wherein the insulating layer of one or more heat-insulating connectors of the plurality of heat-insulating connectors comprises electrically conductive particles to electrically couple the heatsink to the chassis.

6. The electronic device of claim 2, wherein the insulating layer of one or more heat-insulating connectors of the plurality of heat-insulating connectors comprises electrically conductive pins to electrically couple the heatsink to the chassis.

7. The electronic device of claim 2, wherein the mechanical connector comprises a screw or a rivet.

8. The electronic device of claim 1, wherein the heatsink comprises a fan pillow heatsink.

9. A head-mountable device, comprising:
a heatsink;
an electrical circuit mounted on the heatsink;
a display unit coupled to the electrical circuit;
a chassis;
a first plurality of heat-insulating connectors mounting the heatsink to the chassis at a first plurality of mount points;
a first plurality of heat-conducting connectors mounting the heatsink to the chassis at a second plurality of mount points;
an enclosure;
a second plurality of heat-insulating connectors mounting the chassis to the enclosure at a third plurality of mount points; and
a second plurality of heat-conducting connectors mounting the chassis to the enclosure at a fourth plurality of mount points,
wherein the first plurality of mount points are located closer to the electrical circuit mounted on the heatsink than the second plurality of mount points, and
wherein the third plurality of mount points are closer to the electrical circuit mounted on the heatsink than the fourth plurality of mount points.

10. The head-mountable device of claim 9, wherein each heat-insulating connector of the first and second pluralities of heat-insulating connectors comprises:
a mechanical connector; and
an insulating layer separating the mechanical connector from the heatsink and the chassis.

11. The head-mountable device of claim 10, wherein one or more heat-insulating connectors of the first and second pluralities of heat-insulating connectors comprises an electrically conductive wire electrically coupling the heatsink to the chassis or the chassis to the enclosure.

12. The head-mountable device of claim 10, wherein the insulating layer of one or more heat-insulating connectors of the first and second pluralities of heat-insulating connectors comprises electrically conductive particles to electrically couple the heatsink to the chassis or the chassis to the enclosure.

13. The head-mountable device of claim 10, wherein the insulating layer of one or more heat-insulating connectors of the first and second pluralities of heat-insulating connectors comprises electrically conductive pins to electrically couple the heatsink to the chassis or the chassis to the enclosure.

14. The head-mountable device of claim 10, wherein the mechanical connector comprises a screw or a rivet.

15. The head-mountable device of claim 9, wherein the heatsink comprises a fan pillow heatsink.

16. An electronic device, comprising:
a heatsink;
an electrical circuit mounted on the heatsink;
a chassis;
a plurality of heat-insulating connectors mounting the heatsink to the chassis at a first plurality of mount points; and
a plurality of heat-conducting connectors mounting the heatsink to the chassis at a second plurality of mount points.

17. The electronic device of claim 16, wherein the second plurality of mount points are arranged within respective tuned thermal conduction paths between the electrical circuit and the chassis via the heatsink and the plurality of heat-conducting connectors.

18. The electronic device of claim 16, wherein the first plurality of mount points are located closer to the electrical circuit mounted on the heatsink than the second plurality of mount points.

19. The electronic device of claim 16, wherein each heat-insulating connector of the plurality of heat-insulating connectors comprises:
a mechanical connector; and
an insulating layer separating the mechanical connector from the heatsink or the chassis and separating the heatsink from the chassis.

20. The electronic device of claim 19, wherein the insulating layer comprises an electrically conductive material to electrically couple the heatsink to the chassis.
